(19) United States
(12) Patent Application Publication
(10) Pub. No.: US 2026/0126732 A1
(43) Pub. Date: May 7, 2026

(54) METHOD AND APPARATUS FOR DETERMINING PROCESS WINDOW, AND COMPUTER DEVICE

(71) Applicant: INSTITUTE OF MICROELECTRONICS, CHINESE ACADEMY OF SCIENCES, Beijing (CN)

(72) Inventors: Le Ma, Beijing (CN); Yayi Wei, Beijing (CN); Lisong Dong, Beijing (CN); Yajuan Su, Beijing (CN)

(21) Appl. No.: 19/373,015

(22) Filed: Oct. 29, 2025

(30) Foreign Application Priority Data
Nov. 7, 2024 (CN) 202411584831.8

(51) Int. Cl. G03F 7/00

(52) U.S. Cl. CPC G03F 7/706839; G03F 7/70608; G03F 7/70625

(57) ABSTRACT

Provided are a method and an apparatus for determining a process window and a computer device. A surface plasmon photolithography model corresponding to a surface plasmon photolithography structure with an air layer is established. A simulation is performed based on the surface plasmon photolithography model to determine a photoresist pattern formed via photolithography and a critical dimension in the photoresist pattern. A thickness of the air layer and/or exposure energy in the surface plasmon photolithography model are adjusted and the simulation is performed based on the surface plasmon photolithography model repeatedly, to obtain multiple correspondences between the exposure energy, the thickness of the air layer, and the critical dimension. Based on the correspondences and a tolerance range allowed for a critical dimension between the photoresist pattern and a pattern of a mask layer corresponding to the photoresist pattern, the process window corresponding to the mask layer is determined.

### CROSS-REFERENCE TO RELATED APPLICATION

The present application claims the priority to Chinese Patent Application No. 202411584831.8, titled “METHOD AND APPARATUS FOR DETERMINING PROCESS WINDOW,” filed on Nov. 7, 2024 with the China National Intellectual Property Administration, which is incorporated herein by reference in its entirety.

### FIELD

The present disclosure relates to the field of semiconductors, and in particular to a method and an apparatus for determining a process window, and a computer device.

### BACKGROUND

With the development of near-field optics, photolithography methods that break through a diffraction limit, exemplified by a surface plasmon (SP) photolithography method, have gradually been realized. By means of surface plasmon photolithography, a photolithographic pattern with a corresponding dimension much smaller than a wavelength of light from a light source can be obtained based on a long light wavelength. However, this is essentially contact photolithography, which is inefficient, and therefore a surface plasmon photolithography structure with an air layer has been further developed.

In the surface plasmon photolithography structure having an air layer, a mask layer and a photoresist layer are separated by the air layer, which employs near-field projection photolithography in essence. In this way, similar to conventional projection photolithography, a wafer carried by a wafer stage can be moved to expose different regions of the wafer, thereby greatly improving operation efficiency.

In the related art, for the surface plasmon photolithography structure having an air layer, a process window is generally obtained through a manual experiment, which involves constructing a photolithography model manually and setting parameters such as exposure energy. Due to considerable uncertainty inherent in the experiment, the solution wastes a large amount of manpower and resources, and is inefficient. Therefore, how to propose a suitable method for determining a process window is a technical problem to be addressed.

### SUMMARY

In view of this, an objective of the present disclosure is to provide a method and a apparatus for determining a process window, and a computer device. According to the present disclosure, by means of simulation, the process window is determined faster and more accurately, thereby saving materials and time and improving the accuracy of the process window. The solutions are as follows.

In one aspect, a method for determining a process window is provided in the present disclosure. The method includes: a first step of establishing a surface plasmon photolithography model corresponding to a surface plasmon photolithography structure, where the surface plasmon photolithography structure includes a substrate layer, a photoresist layer, an air layer, a metal layer, an insulating layer, and a mask layer which are stacked in sequence; a second step of performing a simulation based on the surface plasmon photolithography model to determine a photoresist pattern formed via photolithography and a critical dimension in the photoresist pattern; a third step of repeatedly adjusting a thickness of the air layer and/or exposure energy in the surface plasmon photolithography model and performing the simulation based on the surface plasmon photolithography model, to obtain multiple correspondences between the exposure energy, the thickness of the air layer, and the critical dimension in the photoresist pattern; and a fourth step of determining, based on the correspondences and a tolerance range allowed for a critical dimension between the photoresist pattern and a pattern of the mask layer corresponding to the photoresist pattern, the process window corresponding to the mask layer.

In an embodiment, the method further includes: repeatedly adjusting the pattern of the mask layer and performing the first step to the fourth step to determine multiple process windows, where each of the multiple process windows corresponds to a pattern of the mask layer; and determining, based on the multiple process windows, a common process window corresponding to multiple patterns of the mask layer.

In an embodiment, the surface plasmon photolithography model includes a spatial light intensity model and a photoresist model, and the second step of performing a simulation based on the surface plasmon photolithography model to determine a photoresist pattern formed via photolithography and a critical dimension in the photoresist pattern includes:
performing a surface plasmon photolithography simulation via the spatial light intensity model to determine a light intensity distribution in the photoresist layer; and simulating, based on the light intensity distribution, a photoresist exposure and development via the photoresist model to determine the photoresist pattern formed via the photolithography and the critical dimension in the photoresist pattern.

In an embodiment, the adjusting the exposure energy in the surface plasmon photolithography model includes: adjusting a light intensity of incident light in the spatial light intensity model, where the light intensity has a one-to-one correspondence with the exposure energy.

In an embodiment, the adjusting the exposure energy in the surface plasmon photolithography model includes: adjusting the exposure energy for the photoresist layer in the photoresist model.

In an embodiment, the performing a surface plasmon photolithography simulation via the spatial light intensity model to determine a light intensity distribution in the photoresist layer includes: performing, in a first simulation software, the surface plasmon photolithography simulation via the spatial light intensity model to determine the light intensity distribution in the photoresist layer; and the simulating, based on the light intensity distribution, a photoresist exposure and development via the photoresist model to determine the photoresist pattern formed via the photolithography and the critical dimension in the photoresist pattern includes: simulating, in a second simulation software, based on the light intensity distribution, the photoresist exposure and development via the photoresist model to determine the photoresist pattern formed via the photolithography and the critical dimension in the photoresist pattern.

In an embodiment, the adjusting a thickness of the air layer and/or exposure energy in the surface plasmon photolithography model includes: adjusting the exposure energy in the surface plasmon photolithography model based on a first preset variation, and adjusting the thickness of the air layer based on a second preset variation.

In an embodiment, the method further includes: repeatedly adjusting a thickness of the metal layer and performing the first step to the fourth step to determine multiple process windows, where each of the multiple process windows corresponds to a thickness of the metal layer; and determining a thickness of the metal layer corresponding to a maximum process window among the multiple process windows, as an optimal thickness of the metal layer of the surface plasmon photolithography structure.

An apparatus for determining a process window is provided in the present disclosure. The apparatus includes: an establishing unit, configured to establish a surface plasmon photolithography model corresponding to a surface plasmon photolithography structure, where the surface plasmon photolithography structure includes a substrate layer, a photoresist layer, an air layer, a metal layer, an insulating layer, and a mask layer which are stacked in sequence; a simulation unit, configured to perform a simulation based on the surface plasmon photolithography model to determine a photoresist pattern formed via photolithography and a critical dimension in the photoresist pattern; and a control unit, configured to repeatedly adjust a thickness of the air layer and/or exposure energy in the surface plasmon photolithography model and perform the simulation based on the surface plasmon photolithography model, to obtain multiple correspondences between the exposure energy, the thickness of the air layer, and the critical dimension in the photoresist pattern, and determine, based on the correspondences and a tolerance range allowed for a critical dimension between the photoresist pattern and a pattern of the mask layer corresponding to the photoresist pattern, the process window corresponding to the mask layer.

In another aspect, a computer device is provided according to an embodiment of the present disclosure. The computer device includes a processor and a memory, where the memory is configured to store program codes; and the processor is configured to, based on the program codes, perform the method according to the foregoing aspect.

The method and the apparatus for determining the process window, and the computer device are provided according to the present disclosure. A surface plasmon photolithography model corresponding to a surface plasmon photolithography structure is established, where the surface plasmon photolithography structure includes a substrate layer, a photoresist layer, an air layer, a metal layer, an insulating layer, and a mask layer which are stacked in sequence. A simulation is performed based on the surface plasmon photolithography model to determine a photoresist pattern formed via photolithography and a critical dimension in the photoresist pattern. A thickness of the air layer and/or exposure energy in the surface plasmon photolithography model are adjusted and the simulation is performed based on the surface plasmon photolithography model repeatedly, to obtain multiple correspondences between the exposure energy, the thickness of the air layer, and the critical dimension in the photoresist pattern. Based on the correspondences and a tolerance range allowed for a critical dimension between the photoresist pattern and a pattern of the mask layer corresponding to the photoresist pattern, the process window corresponding to the mask layer is determined. In summary, in the present disclosure, for a surface plasmon photolithography structure having an air layer, the photolithography process of the structure is simulated, and multiple simulations are performed based on different exposure energy and thicknesses of the air layer. As a result, a process window corresponding to the mask layer is obtained without experiments. This allows faster and more accurate determination of the process window, saves materials and time, improves the determination speed and accuracy for the process window, and enhances a tolerance for process parameter variations for the surface plasmon photolithography.

### BRIEF DESCRIPTION OF THE DRAWINGS

In order to more clearly describe technical solutions in embodiments of the present disclosure or in the conventional technology, drawings to be used in the description of the embodiments of the present disclosure or the conventional technology are briefly described hereinafter. It is apparent that the drawings described below illustrate merely some embodiments of the present disclosure, and those skilled in the art may obtain other drawings based on the provided drawings without any creative effort.

FIG. 1 is a schematic flowchart of a method for determining a process window according to an embodiment of the present disclosure;

FIG. 2 is a schematic diagram of a surface plasmon photolithography structure according to an embodiment of the present disclosure;

FIG. 3 is a schematic diagram of a method for determining a process window according to another embodiment of the present disclosure;

FIG. 4 is a schematic diagram of a process window according to an embodiment of the present disclosure; and

FIG. 5 is a schematic structural diagram of a computer device according to an embodiment of the present disclosure.

### DETAILED DESCRIPTION

In order to make the above objectives, features, and advantages of the present disclosure more apparent and easier to understand, embodiments of the present disclosure are described in detail below in conjunction with the drawings.

Various details are set forth in the following description to facilitate a full understanding of the present disclosure. The present disclosure may be implemented in a manner different from those described herein, and those skilled in the art may perform analogous promotion without departing from concepts of the present disclosure. Therefore, the present disclosure is not limited by the embodiments disclosed hereinafter.

In addition, the present disclosure is described in detail in conjunction with schematic diagrams. To facilitate description in describing embodiments of the present disclosure in detail, a cross-sectional view showing a structure of a device is partially enlarged, not on a general scale. The schematic diagrams are merely exemplary, which are not intended to limit the protection scope of present disclosure. In addition, three-dimensional spatial dimensions of length, width, and depth shall be considered in practice.

For ease of understanding, a method and a related apparatus for determining a process window according to the embodiments of the present disclosure are described in detail below with reference to the drawings.

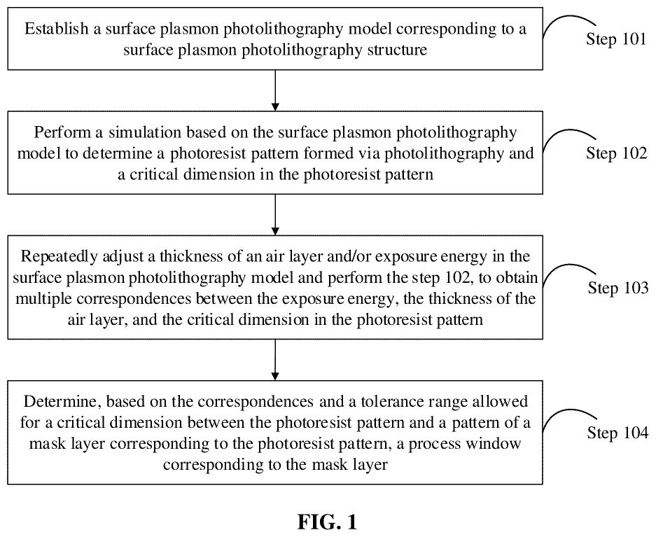

Reference is made to FIG. 1, which is a schematic flowchart of a method for determining a process window according to an embodiment of the present disclosure, and the method may include the following steps 101 to 104.

In step 101, a surface plasmon photolithography model corresponding to a surface plasmon photolithography structure is established.

In an embodiment of the present disclosure, the surface plasmon photolithography structure may include a substrate layer, a photoresist (PR) layer, an air layer, a metal layer, an insulating layer, and a mask layer which are stacked in sequence. The substrate layer is used to provide support, and for example, it may be a silicon substrate. The air layer is a layer containing air, and its thickness may be several tens of nanometers. The mask layer may be made of, for example, chromium (Cr), and under illumination of incident light, a pattern of the mask layer can be transferred to the photoresist layer.

The metal layer may be, for example, a gold (Au), silver (Ag), or aluminum (Al) layer, and the insulating layer may be, for example, a polymethyl methacrylate (PMMA) layer. When exposed to electromagnetic waves at specific wavelengths, the metal layer has a negative dielectric constant, while the insulating layer has a positive dielectric constant. One of the conditions for the generation of surface plasmons is that the dielectric constants of the metal layer and the insulating layer have opposite signs. Thus, surface plasmons can be generated at an interface between the metal layer and the insulating layer as film layers. In addition, the excitation of surface plasmons requires that the incident electromagnetic wave exhibits transverse magnetic (TM) polarization mode.

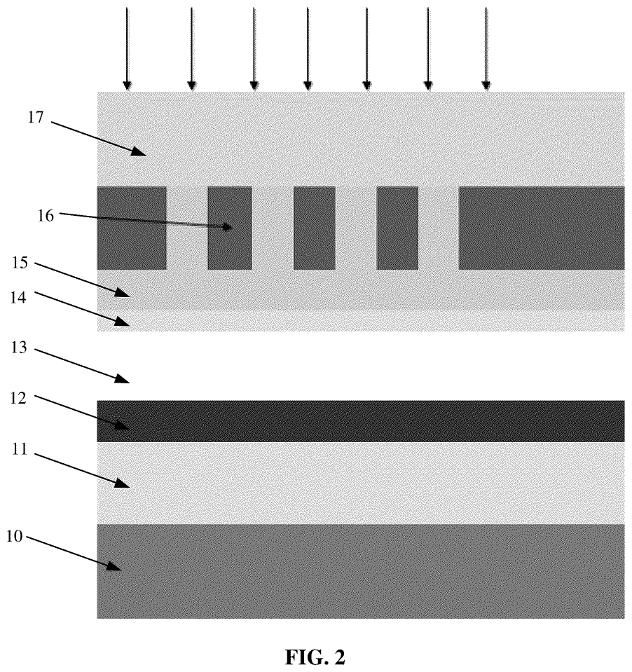

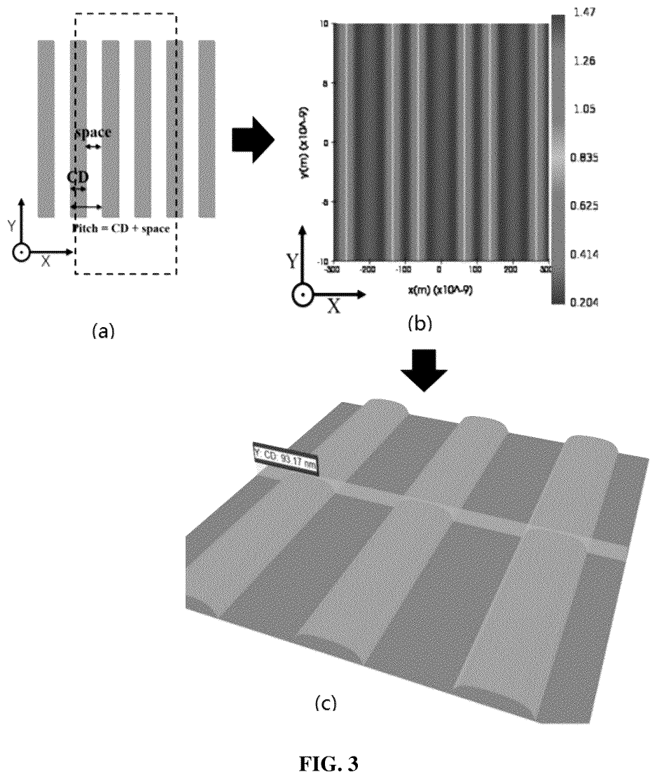

Reference is made to FIG. 2, which is a schematic diagram of a surface plasmon photolithography structure according to an embodiment of the present disclosure. The surface plasmon photolithography structure may include a substrate layer 10, a silver layer 11, a photoresist layer 12, an air layer 13, a metal layer 14, an insulating layer 15, a mask layer 16, and a quartz layer 17, which are stacked in sequence. Incident light is irradiated on the surface plasmon photolithography structure from top to bottom, and the silver layer 11 is for enhancing light reflection. As shown in (a) of FIG. 3, a top view of the mask layer is illustrated, including multiple lines.

In practical production, a variation in exposure energy and a focus value occurs in a photolithography machine due to various factors, causing them to deviate from corresponding set values. The deviation in the exposure energy often originates from the instability of the light source, while the deviation in the focus value often originates from inherent deviations of a lens assembly and mechanical deviations in focus position control.

The process window defines allowable variation ranges for the exposure energy and the focus value. When the photoresist layer is exposed with a pattern of the mask layer based on the variation ranges, a deviation between a pattern in the photoresist layer and the pattern of the mask layer remains within an acceptable range. For example, when exposure is performed with the exposure energy in a range of 16 to 22mJ/cm² and the focus value in a range of −0.15 to +0.1 μm, a critical dimension (CD) in the pattern in the photoresist layer ranges from 135nm to 165nm, that is, the deviation is within ±15 nm (where a deviation of 10% is within the acceptable range).

For a surface plasmon photolithography structure with an air layer, a thickness of the air layer is similar to a focus value in conventional projection photolithography, and thus the focus value is determined based on a thickness of the air layer. In this case, the deviation in exposure energy originates from the instability of the light source, while a deviation in the thickness of the air layer originates from the mechanical control.

In an embodiment, a simulation model corresponding to the surface plasmon photolithography structure may be established in a simulation software, and this simulation model is referred to as a surface plasmon photolithography model, to facilitate subsequent simulation analysis of the photolithography process.

In step 102, a simulation is performed based on the surface plasmon photolithography model to determine a photoresist pattern formed via photolithography and a critical dimension in the photoresist pattern.

In an embodiment, the surface plasmon photolithography model is used to perform a simulation of a photolithography process to simulate the pattern formed in the photoresist layer under the effect of the mask layer, that is, the photoresist pattern, thereby obtaining the photoresist pattern formed via the photolithography and a width of a line (critical dimension, CD) in the photoresist pattern.

In an embodiment, during the simulation process, a process of light shining on the surface plasmon photolithography structure is simulated, and the pattern formed in the photoresist layer under illumination is simulated.

In an implementation, the surface plasmon photolithography model includes a spatial light intensity model and a photoresist model. And the step 102, in which a simulation is performed based on the surface plasmon photolithography model to determine a photoresist pattern formed via photolithography and a critical dimension in the photoresist pattern may include: performing a surface plasmon photolithography simulation via the spatial light intensity model to determine a light intensity distribution in the photoresist layer; and simulating, based on the light intensity distribution, a photoresist exposure and development via the photoresist model to determine the photoresist pattern formed via the photolithography and the critical dimension in the photoresist pattern.

In an embodiment, the surface plasmon photolithography model may include two independent models, namely a spatial light intensity model and a photoresist model. A structure of film layers in the spatial light intensity model is the same as that in the surface plasmon photolithography structure, and the spatial light intensity model is mainly used to simulate the light intensity distribution in the photoresist layer. That is, electromagnetic field simulation may be performed based on the properties of each film layer, such as material, thickness, and refractive index, as well as the light intensity of incident light for the spatial light intensity model, so as to obtain the light intensity distribution in the photoresist layer.

Thus, based on the spatial light intensity model, the light intensity distribution of a light which is formed by the incident light passing through corresponding film layers and suffering the effect applied by corresponding film layers, and is finally directed to the photoresist layer is determined, without manual experiments. In addition, the light intensity distribution in the photoresist layer may be outputted as light intensity data. Reference is made to (b) of FIG. 3, which illustrates the light intensity distribution in the photoresist layer.

After determining the light intensity distribution in the photoresist layer, the exposure of the photoresist layer under the light intensity distribution is required to be simulated, that is, it is required to determine that which portions of the photoresist layer should be retained or removed, so as to form the pattern in the photoresist layer consistent with the pattern of the mask layer.

The photoresist model may include only a single photoresist layer, or may further include other film layers under the photoresist layer. In an embodiment, simulation may be performed through the photoresist model based on the light intensity distribution, thereby obtaining the photoresist pattern formed via the photolithography. In this manner, based on certain incident light energy, thickness of the air layer, and pattern of the mask layer, the critical dimension in the photoresist pattern formed via the photolithography can be determined.

As a result, by separately simulating the light intensity distribution in the photoresist layer via the spatial light intensity model and the photoresist pattern formed under the light intensity distribution via the photoresist model, each simulation result is more accurate, thereby enabling more precise simulation of the photolithography process.

In an embodiment, the performing a surface plasmon photolithography simulation via the spatial light intensity model to determine a light intensity distribution in the photoresist layer may include: performing, in a first simulation software, the surface plasmon photolithography simulation via the spatial light intensity model to determine the light intensity distribution in the photoresist layer. And the simulating, based on the light intensity distribution, a photoresist exposure and development via the photoresist model to determine the photoresist pattern formed via the photolithography and the critical dimension in the photoresist pattern may include: simulating, in a second simulation software, based on the light intensity distribution, the photoresist exposure and development via the photoresist model to determine the photoresist pattern formed via the photolithography and the critical dimension in the photoresist pattern.

In an embodiment, in the first simulation software, the spatial light intensity model corresponding to the surface plasmon photolithography structure may be established. The first simulation software may include a FDTD simulation software or an RCWA simulation software, but is not limited thereto. The first simulation software is only required to have a capability to simulate light intensity, that is, a capability of determining the light intensity distribution in the photoresist layer through an electromagnetic field simulation method. By performing a simulation with the first simulation software via the spatial light intensity model, the light intensity distribution can be obtained.

In an embodiment, in the second simulation software, the photoresist model may be established. The second simulation software is used for simulating, based on a certain light intensity distribution, to obtain the pattern formed in the photoresist layer. The second simulation software may include Prolith simulation software or S-litho simulation software, but is not limited thereto. The first simulation software and the second simulation software may be installed on a same computer.

The light intensity distribution in the photoresist layer output by the first simulation software may be input into the second simulation software. Accordingly, the second simulation software may perform simulation via the photoresist model based on the light intensity distribution, thereby obtaining the photoresist pattern formed via the photolithography. In addition, the second simulation software may also output the critical dimension and pitch in the photoresist pattern. Reference is made to (c) in FIG. 3, which illustrates the photoresist pattern formed via the photolithography, including three lines.

In this way, by combining the first simulation software and the second simulation software for simulation, and adjusting the exposure energy and the thickness of the air layer, the process window corresponding to the mask layer is obtained, so that the experiment is not required. Thus, the process window is determined faster and more accurately, thereby saving materials and time, and improving the speed and accuracy for determining the process window. In addition, the feasibility of the process can be evaluated faster without conducting experiments, thereby improving process efficiency.

In step 103, a thickness of the air layer and/or exposure energy in the surface plasmon photolithography model are adjusted and the step 102 is performed repeatedly, to obtain multiple correspondences between the exposure energy, the thickness of the air layer, and the critical dimension in the photoresist pattern.

In an embodiment, in order to determine a process window for a certain pattern of the mask layer, the thickness of the air layer and/or the exposure energy in the surface plasmon photolithography model may be adjusted. Each time the exposure energy or the thickness of the air layer is adjusted, the steps 101 to 102 may be performed to obtain the critical dimension in the photoresist pattern corresponding to the adjusted exposure energy or the adjusted thickness of the air layer. The thickness of the air layer may be directly modified in the first simulation software, while the exposure energy may be adjusted in both the first simulation software and the second simulation software.

For example, a pattern of the mask layer is defined as a line pattern with a CD=90 nm and a pitch=180 nm. The thickness of the air layer is set to 50 nm, and the exposure energy is initially set to 10 mj/cm², then gradually increased to 18 mj/cm² in increments of 0.1 mj/cm². Accordingly, CDs in the photoresist patterns corresponding to different exposure energy can be obtained. Assuming 10% is an allowable tolerance, the exposure energy corresponding to CDs in the photoresist patterns in a range of 81 nm to 99 nm is recorded.

The thickness of the air layer is set to 51 nm, and the steps 101 to 104 are performed; the thickness of the air layer is then set to 52 nm, and the steps 101 to 104 are performed, and so on, until sufficient data are obtained.

As a result, the multiple correspondences between the exposure energy, the thickness of the air layer, and the critical dimension in the photoresist pattern are obtained. That is, a set of exposure energy, thickness of the air layer, and pattern of the mask layer corresponds to the critical dimension in the pattern formed in the photoresist layer.

In an embodiment, the adjusting the exposure energy in the surface plasmon photolithography model may include: adjusting a light intensity of incident light in the spatial light intensity model, where the light intensity has a one-to-one correspondence with the exposure energy.

In an embodiment, a light intensity of incident light irradiated to the surface plasmon photolithography structure may be adjusted in the spatial light intensity model. Since the light intensity is proportional to the square of the amplitude, the amplitude of the incident light may be adjusted. Different light intensities correspond to different exposure energy. Adjusting the light intensity of the incident light in the spatial light intensity model is equivalent to adjusting the exposure energy, and by adjusting the light intensity of the incident light, a more accurate process window can be obtained.

In an embodiment, the adjusting the exposure energy in the surface plasmon photolithography model may include: adjusting the exposure energy for the photoresist layer in the photoresist model.

In an embodiment, the exposure energy may be adjusted in the photoresist model. That is, in the spatial light intensity model, the light intensities of the incident light are all set to a same value, and the exposure energy is set in the photoresist model. The light intensity distribution is adjusted in the photoresist model based on the set exposure energy, so that the adjusted light intensity distribution is applied to the photoresist model to output the critical dimension in the photoresist pattern. In this way, by directly setting the exposure energy, the exposure energy can be adjusted more conveniently, thereby improving the flexibility of exposure energy adjustment.

In an embodiment, the adjusting a thickness of the air layer and/or exposure energy in the surface plasmon photolithography model may include: adjusting the exposure energy in the surface plasmon photolithography model based on a first preset variation, and adjusting the thickness of the air layer based on a second preset variation.

That is, each time the exposure energy is adjusted, it is increased or decreased by a same variation, namely the first preset variation, and each time the thickness of the air layer is adjusted, it is increased or decreased by a same variation, namely the second preset variation, so that the critical dimensions corresponding to the exposure energy or the air layer thickness are obtained in a uniform manner, thereby causing the variation of independent variables in the correspondences to be more balanced and the data to be more complete and sufficient.

In step 104, based on the correspondences and a tolerance range allowed for a critical dimension between the photoresist pattern and a pattern of the mask layer corresponding to the photoresist pattern, the process window corresponding to the mask layer is determined.

In an embodiment, the correspondences may reflect the critical dimension in the pattern in the photoresist layer formed based on certain exposure energy, thickness of the air layer, and pattern of the mask layer. The allowable tolerance range refers to an allowable preset range for a critical dimension difference between the photoresist pattern and the pattern of the mask layer, and the manufacturing process is not affected when the critical dimension difference is within the allowable tolerance range.

Based on the allowable tolerance range, critical dimensions (where the critical dimension differences are within the allowable tolerance range) may be determined from the correspondences, and ranges for the exposure energy and thicknesses of the air layer corresponding to the critical dimensions are determined as the process window corresponding to the mask layer. The process window corresponding to the mask layer refers to a process window corresponding to the pattern of the mask layer. The process window may be represented with a coordinate graph. As shown in FIG. 4, the horizontal axis represents the thickness of the air layer, and the vertical axis represents the exposure energy, with the rectangular area in the figure representing the process window.

Therefore, in the present disclosure, for the surface plasmon photolithography structure with the air layer, the photolithography process of the structure is simulated, and multiple simulations are performed based on different exposure energy and thicknesses of the air layer, thereby obtaining the process window corresponding to the mask layer without experiments. This allows faster and more accurate determination of the process window, saves materials and time, improves the determination speed and accuracy for the process window, and enhances a tolerance for process parameter variations for the surface plasmon photolithography.

In an implementation, the pattern of the mask layer is adjusted and the steps 101 to 104 are performed repeatedly, to determine multiple process windows; based on the multiple process windows, a common process window corresponding to multiple patterns of the mask layer is determined.

In an embodiment, the pattern of the mask layer may also be adjusted. For example, the critical dimension or the pitch in the pattern of the mask layer may be adjusted. Each time the pattern of the mask layer is changed, steps 101 to 104 are performed to determine the process window corresponding to each mask layer, that is, each process window corresponds to a pattern of the mask layer.

For the multiple process windows corresponding to multiple patterns of the mask layer, a overlapping portion of the multiple process windows may be determined as the common process window. Based on the common process window, the photoresist patterns respectively corresponding to the multiple patterns of the mask layer can be obtained, where the critical dimension differences between the photoresist patterns and the patterns of the mask layer are within the allowable tolerance range.

In this way, simulations are conducted for the multiple patterns of the mask layer, so that the common process window can be determined faster and more accurately without manual experiments, thereby greatly saving experimental time and allowing more flexible adjustment of the patterns of the mask layer.

In an embodiment, a thickness of the metal layer is adjusted and the steps 101 to 104 are performed repeatedly, to determine multiple process windows, where each of the multiple process windows corresponds to a thickness of the metal layer. A thickness of the metal layer corresponding to a maximum process window among the multiple process windows, is determined as an optimal thickness of the metal layer of the surface plasmon photolithography structure.

In an embodiment, the thicknesses of various film layers in the surface plasmon photolithography structure may also be adjusted. For example, the thickness of the metal layer may be adjusted, so as to determine process windows corresponding to each thickness of the metal layer, respectively. The thickness of the metal layer corresponding to the maximum process window may be determined as the optimal thickness of the metal layer, thereby expanding the process window to the greatest extent based on the adjustment of the film layer structure. In addition, the materials of the film layers may be changed, and the process windows corresponding to different materials may be calculated. A material of the film layer corresponding to the maximum process window may be determined as an optimal material.

Based on the above method for determining the process window, an apparatus for determining the process window is further provided according to the embodiment of the present disclosure, and the apparatus may include: an establishing unit, a simulation unit and a control unit.

The establishing unit is configured to establish a surface plasmon photolithography model corresponding to a surface plasmon photolithography structure, where the surface plasmon photolithography structure includes a substrate layer, a photoresist layer, an air layer, a metal layer, an insulating layer, and a mask layer which are stacked in sequence.

The simulation unit is configured to perform a simulation based on the surface plasmon photolithography model to determine a photoresist pattern formed via photolithography and a critical dimension in the photoresist pattern.

The control unit is configured to repeatedly adjust a thickness of the air layer and/or exposure energy in the surface plasmon photolithography model and perform the simulation based on the surface plasmon photolithography model, to obtain multiple correspondences between the exposure energy, the thickness of the air layer, and the critical dimension in the photoresist pattern, and determine, based on the correspondences and a tolerance range allowed for a critical dimension between the photoresist pattern and a pattern of the mask layer corresponding to the photoresist pattern, the process window corresponding to the mask layer.

In an embodiment, the control unit is further configured to: repeatedly adjust the pattern of the mask layer and perform the steps 101 to 104 to determine multiple process windows, where each of the multiple process windows corresponds to a pattern of the mask layer; and determine, based on the multiple process windows, a common process window corresponding to multiple patterns of the mask layer.

In an embodiment, the surface plasmon photolithography model includes a spatial light intensity model and a photoresist model.

The simulation unit is configured to: perform a surface plasmon photolithography simulation via the spatial light intensity model to determine a light intensity distribution in the photoresist layer; and simulate, based on the light intensity distribution, a photoresist exposure and development via the photoresist model to determine the photoresist pattern formed via the photolithography and the critical dimension in the photoresist pattern.

In an embodiment, the simulation unit is configured to: adjust a light intensity of incident light in the spatial light intensity model, where the light intensity has a one-to-one correspondence with the exposure energy.

In an embodiment, the simulation unit is configured to: adjust the exposure energy for the photoresist layer in the photoresist model.

In an embodiment, the simulation unit is configured to: perform, in a first simulation software, the surface plasmon photolithography simulation via the spatial light intensity model to determine the light intensity distribution in the photoresist layer; and the simulating, based on the light intensity distribution, a photoresist exposure and development via the photoresist model to determine the photoresist pattern formed via the photolithography and the critical dimension in the photoresist pattern includes: simulating, in a second simulation software, based on the light intensity distribution, the photoresist exposure and development via the photoresist model to determine the photoresist pattern formed via the photolithography and the critical dimension in the photoresist pattern.

In an embodiment, the control unit is configured to: adjust the exposure energy in the surface plasmon photolithography model based on a first preset variation, and adjust the thickness of the air layer based on a second preset variation.

In an embodiment, the control unit is configured to: repeatedly adjust a thickness of the metal layer and perform the steps 101 to 104 to determine multiple process windows, where each of the multiple process windows corresponds to a thickness of the metal layer; and determine a thickness of the metal layer corresponding to a maximum process window among the multiple process windows, as an optimal thickness of the metal layer of the surface plasmon photolithography structure.

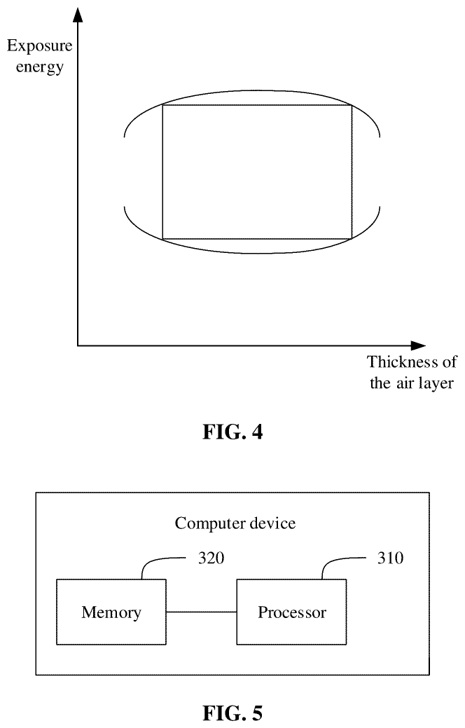

In another aspect, a computer device is further provided according to the embodiment of the present disclosure. Reference is made to FIG. 5, which is a schematic structural diagram of a computer device according to an embodiment of the present disclosure. The computer device includes a processor 310 and a memory 320.

The memory 320 is configured to store program codes.

The processor 310 is configured to, based on the program codes, perform the method provided in the above embodiments.

The computer device may include a terminal device or a server, and the aforementioned apparatus may be configured in the computer device.

Those skilled in the art can understand that all or part of the steps of the above method embodiments may be implemented by program instructions and hardware. The program may be stored in a computer-readable storage medium, and when executed, the program performs the steps including the above method embodiments. The storage medium may be at least one of the following: a read-only memory (ROM), a random-access memory (RAM), a magnetic disk, or an optical disk, or any other medium capable of storing program codes.

The embodiments in the present disclosure are described in a progressive manner, the same and similar parts of the various embodiments in this specification can be referred to each other, and each embodiment focuses on the differences from other embodiments. In particular, the apparatus embodiment is substantially similar to the method embodiment, therefore is described relatively simple, and reference may be made to the relevant portions of the method embodiment for details.

The above description is only preferred embodiments of the present disclosure. Although the present disclosure has been disclosed with reference to the above preferred embodiments, it is not intended to limit the present disclosure. Any person skilled in the art may, without departing from the scope of the technical solution of the present disclosure, can make various modifications and variations, or modify the embodiments into equivalent embodiments based on the methods and technical content disclosed above. Therefore, any simple modifications, equivalent variations, and adaptations of the above embodiments based on the technical essence of the present disclosure that do not depart from the technical solution of the present disclosure shall still fall within the scope protected by the technical solution of the present disclosure.

1. A method for determining a process window, comprising:
a first step of establishing a surface plasmon photolithography model corresponding to a surface plasmon photolithography structure, wherein the surface plasmon photolithography structure comprises a substrate layer, a photoresist layer, an air layer, a metal layer, an insulating layer, and a mask layer which are stacked in sequence;
a second step of performing a simulation based on the surface plasmon photolithography model to determine a photoresist pattern formed via photolithography and a critical dimension in the photoresist pattern;
a third step of repeatedly adjusting a thickness of the air layer and/or exposure energy in the surface plasmon photolithography model and performing the simulation based on the surface plasmon photolithography model, to obtain a plurality of correspondences between the exposure energy, the thickness of the air layer, and the critical dimension in the photoresist pattern; and
a fourth step of determining, based on the correspondences and a tolerance range allowed for a critical dimension between the photoresist pattern and a pattern of the mask layer corresponding to the photoresist pattern, the process window corresponding to the mask layer.

2. The method according to claim 1, further comprising:
repeatedly adjusting the pattern of the mask layer and performing the first step to the fourth step to determine a plurality of process windows, wherein each of the plurality of process windows corresponds to a pattern of the mask layer; and
determining, based on the plurality of process windows, a common process window corresponding to a plurality of patterns of the mask layer.

3. The method according to claim 1, wherein the surface plasmon photolithography model comprises a spatial light intensity model and a photoresist model, and
the second step of performing a simulation based on the surface plasmon photolithography model to determine a photoresist pattern formed via photolithography and a critical dimension in the photoresist pattern comprises:
performing a surface plasmon photolithography simulation via the spatial light intensity model to determine a light intensity distribution in the photoresist layer; and
simulating, based on the light intensity distribution, a photoresist exposure and development via the photoresist model to determine the photoresist pattern formed via the photolithography and the critical dimension in the photoresist pattern.

4. The method according to claim 2, wherein the surface plasmon photolithography model comprises a spatial light intensity model and a photoresist model, and
the second step of performing a simulation based on the surface plasmon photolithography model to determine a photoresist pattern formed via photolithography and a critical dimension in the photoresist pattern comprises:
performing a surface plasmon photolithography simulation via the spatial light intensity model to determine a light intensity distribution in the photoresist layer; and
simulating, based on the light intensity distribution, a photoresist exposure and development via the photoresist model to determine the photoresist pattern formed via the photolithography and the critical dimension in the photoresist pattern.

5. The method according to claim 3, wherein the adjusting the exposure energy in the surface plasmon photolithography model comprises:
adjusting a light intensity of incident light in the spatial light intensity model, wherein the light intensity has a one-to-one correspondence with the exposure energy.

6. The method according to claim 4, wherein the adjusting the exposure energy in the surface plasmon photolithography model comprises:
adjusting a light intensity of incident light in the spatial light intensity model, wherein the light intensity has a one-to-one correspondence with the exposure energy.

7. The method according to claim 3, wherein the adjusting the exposure energy in the surface plasmon photolithography model comprises:
adjusting the exposure energy for the photoresist layer in the photoresist model.

8. The method according to claim 4, wherein the adjusting the exposure energy in the surface plasmon photolithography model comprises:
adjusting the exposure energy for the photoresist layer in the photoresist model.

9. The method according to claim 3, wherein the performing a surface plasmon photolithography simulation via the spatial light intensity model to determine a light intensity distribution in the photoresist layer comprises:
performing, in a first simulation software, the surface plasmon photolithography simulation via the spatial light intensity model to determine the light intensity distribution in the photoresist layer; and
the simulating, based on the light intensity distribution, a photoresist exposure and development via the photoresist model to determine the photoresist pattern formed via the photolithography and the critical dimension in the photoresist pattern comprises:
simulating, in a second simulation software, based on the light intensity distribution, the photoresist exposure and development via the photoresist model to determine the photoresist pattern formed via the photolithography and the critical dimension in the photoresist pattern.

10. The method according to claim 4, wherein the performing a surface plasmon photolithography simulation via the spatial light intensity model to determine a light intensity distribution in the photoresist layer comprises:
performing, in a first simulation software, the surface plasmon photolithography simulation via the spatial light intensity model to determine the light intensity distribution in the photoresist layer; and
the simulating, based on the light intensity distribution, a photoresist exposure and development via the photoresist model to determine the photoresist pattern formed via the photolithography and the critical dimension in the photoresist pattern comprises:
simulating, in a second simulation software, based on the light intensity distribution, the photoresist exposure and development via the photoresist model to determine the photoresist pattern formed via the photolithography and the critical dimension in the photoresist pattern.

11. The method according to claim 1, wherein the adjusting a thickness of the air layer and/or exposure energy in the surface plasmon photolithography model comprises:
adjusting the exposure energy in the surface plasmon photolithography model based on a first preset variation, and adjusting the thickness of the air layer based on a second preset variation.

12. The method according to claim 1, further comprising:
repeatedly adjusting a thickness of the metal layer and performing the first step to the fourth step to determine a plurality of process windows, wherein each of the plurality of process windows corresponds to a thickness of the metal layer; and
determining a thickness of the metal layer corresponding to a maximum process window among the plurality of process windows, as an optimal thickness of the metal layer of the surface plasmon photolithography structure.

13. A computer device, comprising a processor and a memory, wherein
the memory is configured to store program codes; and
the processor is configured to, based on the program codes, perform
a first step: establish a surface plasmon photolithography model corresponding to a surface plasmon photolithography structure, wherein the surface plasmon photolithography structure comprises a substrate layer, a photoresist layer, an air layer, a metal layer, an insulating layer, and a mask layer which are stacked in sequence;
a second step: perform a simulation based on the surface plasmon photolithography model to determine a photoresist pattern formed via photolithography and a critical dimension in the photoresist pattern;
a third step: repeatedly adjust a thickness of the air layer and/or exposure energy in the surface plasmon photolithography model and perform the simulation based on the surface plasmon photolithography model, to obtain a plurality of correspondences between the exposure energy, the thickness of the air layer, and the critical dimension in the photoresist pattern; and
a fourth step: determine, based on the correspondences and a tolerance range allowed for a critical dimension between the photoresist pattern and a pattern of the mask layer corresponding to the photoresist pattern, the process window corresponding to the mask layer.

14. The computer device according to claim 13, wherein the processor is further configured to, based on the program codes:
repeatedly adjust the pattern of the mask layer and perform the first step to the fourth step to determine a plurality of process windows, wherein each of the plurality of process windows corresponds to a pattern of the mask layer; and
determine, based on the plurality of process windows, a common process window corresponding to a plurality of patterns of the mask layer.

15. The computer device according to claim 13, wherein the surface plasmon photolithography model comprises a spatial light intensity model and a photoresist model, and
the processor is further configured to, based on the program codes:
perform a surface plasmon photolithography simulation via the spatial light intensity model to determine a light intensity distribution in the photoresist layer; and
simulate, based on the light intensity distribution, a photoresist exposure and development via the photoresist model to determine the photoresist pattern formed via the photolithography and the critical dimension in the photoresist pattern.

16. The computer device according to claim 14, wherein the surface plasmon photolithography model comprises a spatial light intensity model and a photoresist model, and
the processor is further configured to, based on the program codes:
perform a surface plasmon photolithography simulation via the spatial light intensity model to determine a light intensity distribution in the photoresist layer; and
simulate, based on the light intensity distribution, a photoresist exposure and development via the photoresist model to determine the photoresist pattern formed via the photolithography and the critical dimension in the photoresist pattern.

17. The computer device according to claim 15, wherein the processor is further configured to, based on the program codes:
adjust a light intensity of incident light in the spatial light intensity model, wherein the light intensity has a one-to-one correspondence with the exposure energy.

18. The computer device according to claim 16, wherein the processor is further configured to, based on the program codes:
adjust a light intensity of incident light in the spatial light intensity model, wherein the light intensity has a one-to-one correspondence with the exposure energy.

19. The computer device according to claim 15, wherein the processor is further configured to, based on the program codes:
adjust the exposure energy for the photoresist layer in the photoresist model.

20. The computer device according to claim 16, wherein the processor is further configured to, based on the program codes:
adjust the exposure energy for the photoresist layer in the photoresist model.
